(19) United States
(12) Patent Application Publication
(10) Pub. No.: US 2024/0338050 A1
(43) Pub. Date: Oct. 10, 2024

(54) Adiabatic Stepwise Clock Architecture

(71) Applicant: Arm Limited, Cambridge (GB)

(72) Inventors: Cyrille Nicolas Dray, Antibes (FR); Mouhamad Alayan, Antibes (FR); Cedric Normand, Villeneuve-Loubet (FR)

(21) Appl. No.: 18/132,063

(22) Filed: Apr. 7, 2023

(51) Int. Cl. G06F 1/06; H03K 17/56

(52) U.S. Cl. CPC G06F 1/06; H03K 17/56

(57) ABSTRACT

Various implementations described herein are directed to a device having a clock driver that provides an adiabatic stepwise clock signal via an output node, and the clock driver may be coupled between a supply voltage and ground. Also, the device may have selectively switched stages with each selectively switched stage having a capacitor and a transistor coupled in series between the output node and ground. In some instances, each capacitor may refer to an auxiliary tank capacitor that is electrically isolated from each other auxiliary tank capacitor.

### BACKGROUND

This section is intended to provide information relevant to understanding the various technologies described herein. As the section's title implies, this is a discussion of related art that should in no way imply that it is prior art. Generally, the related art may or may not be considered prior art. It should therefore be understood that any statement in this section should be read in this light, and not as any admission of prior art.

In various circuit architectures, some clock circuitry designs may typically have multiple voltage supplies that need multiple voltage regulators for providing and driving clock tree power. These clock circuitry designs adversely impact area and are typically impractical due to large footprint on silicon. Also, some clock circuitry designs typically implement use of substantially large MOS based capacitors that are not practical due to the large area needed on silicon. Thus, since these clock circuit designs require an excessively large amount of space on silicon, these types of clock circuits are cumbersome, inefficient and impractical to implement with the multiple voltage supplies, multiple voltage regulators and large MOS based capacitors. Therefore, in these types of clock circuits, there exists a need for area efficient circuitry that efficiently reduces the area impact of clocking architecture for practical use.

### BRIEF DESCRIPTION OF THE DRAWINGS

Implementations of various techniques are described herein with reference to the accompanying drawings. It should be understood, however, that the accompanying drawings illustrate only various implementations described herein and are not meant to limit embodiments of various techniques described herein.

FIG. 1 illustrates a diagram of adiabatic clock architecture in accordance with various implementations described herein.

FIG. 2 illustrates a waveform diagram of stepwise operation of adiabatic clock architecture in accordance with various implementations described herein.

FIG. 3 illustrates a diagram of adiabatic clock architecture in accordance with various implementations described herein.

FIG. 4A-4B illustrate various clocking operational diagrams for adiabatic clock architecture in accordance with various implementations described herein.

FIG. 5A-5B illustrate various clocking operational diagrams for adiabatic clock architecture in accordance with various implementations described herein.

FIG. 6 illustrates a process diagram of a method for providing adiabatic clock architecture in accordance with various implementations described herein.

### DETAILED DESCRIPTION

Various implementations described herein are directed to adiabatic stepwise clocking schemes and techniques for various circuit related architectural applications in physical designs. Also, in some implementations, the various adiabatic stepwise clocking schemes and techniques described herein provide for a novel adiabatic stepwise clocking architecture having a clock driver with selectively switched stages having a capacitor and a transistor that are configured to output an adiabatic stepwise clock signal. Also, in some implementations, the various schemes and techniques described herein may provide for use of auxiliary tank capacitors that are physically separated and electrically isolated from each other auxiliary tank capacitor. Also, the various schemes and techniques described herein use MIMCAPs (metal-insulator-metal capacitors) as auxiliary tank capacitors.

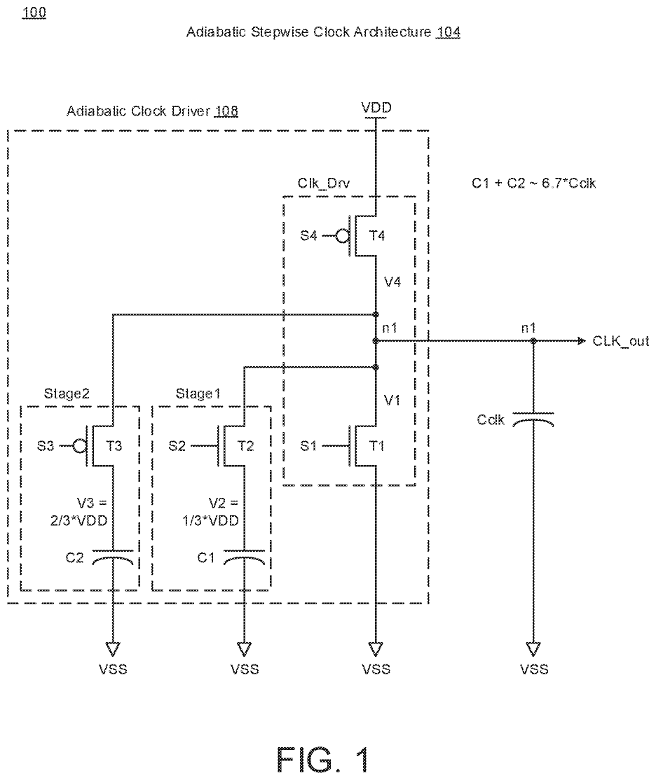

Various implementations of adiabatic stepwise clocking techniques for various circuit applications will be described in greater detail herein in FIGS. 1-6.

FIG. 1 illustrates a schematic diagram 100 of adiabatic clock architecture 104 in accordance with various implementations described herein.

In various implementations, the adiabatic clock architecture 104 in FIG. 1 may refer to adiabatic stepwise clocking architecture that may be implemented as a system or a device having various integrated circuit (IC) components that are arranged and coupled together as an assemblage or some combination of parts that provide for physical circuit designs and related structures. In some instances, a method of designing, providing and fabricating adiabatic clock architecture 104 as an integrated system or device may involve use of various IC circuit components and/or structures described herein so as to thereby implement fabrication schemes and techniques associated therewith. Also, the adiabatic clock architecture 104 may be integrated with various computing circuitry and/or related components on a single chip, and in addition, the adiabatic clock architecture 104 may be implemented in various embedded devices or systems for automotive, mobile, computer, server and Internet-of-things (loT) applications, including remote sensor nodes.

As shown in FIG. 1, the adiabatic clock architecture 104 may refer to adiabatic stepwise clocking architecture for various circuit related applications. Also, the adiabatic clock architecture 104 may include adiabatic clock driver circuitry 108 having a clock driver (Clk_Drv) and selectively switched stages (Stage1, Stage2) that are configured to provide for adiabatic stepwise clock signal (CLK_out) as output. Also, the clock driver (Clk_Drv) provides the adiabatic stepwise clock signal (CLK_out) via the output node (n1), and the clock driver (Clk_Drv) may be coupled between a supply voltage (VDD) and ground (VSS or GND). Also, the clock driver (Clk_Drv) may include transistors (T1, T4) that are coupled in series between supply voltage (VDD) and ground (VSS or GND) with the output node (n1) disposed between transistors (T1, T4). Also, in some instances, each selectively switched stage (Stage1, Stage2) may include a capacitor (C1, C2) and a transistor (T2, T3) that are coupled in series between the output node (n1) and ground (VSS or GND), and also, each capacitor (C1, C2) may be implemented as an auxiliary tank capacitor that is separated (e.g., physically separated) and/or isolated (e.g., electrically isolated) from each other auxiliary tank capacitor.

In various implementations, the clock driver (Clk_Drv) may include one or more transistors, including, e.g., a first transistor (T1) that is coupled between the output node (n1) and ground (VSS or GND), and when selectively activated with a first switch signal (S1), the clock driver (Clk_Drv) may provide a first voltage (V1) that is approximately equal to or at least similar to ground (VSS or GND) and/or ground voltage. Also, the clock driver (Clk_Drv) may include a fourth transistor (T4) that is coupled between the supply voltage (VDD) and the output node (n1), and when selectively activated with a fourth switch signal (S4), the clock driver (Clk_Drv) may provide a fourth voltage (V4) that is approximately equal to or at least similar to the supply voltage (VDD).

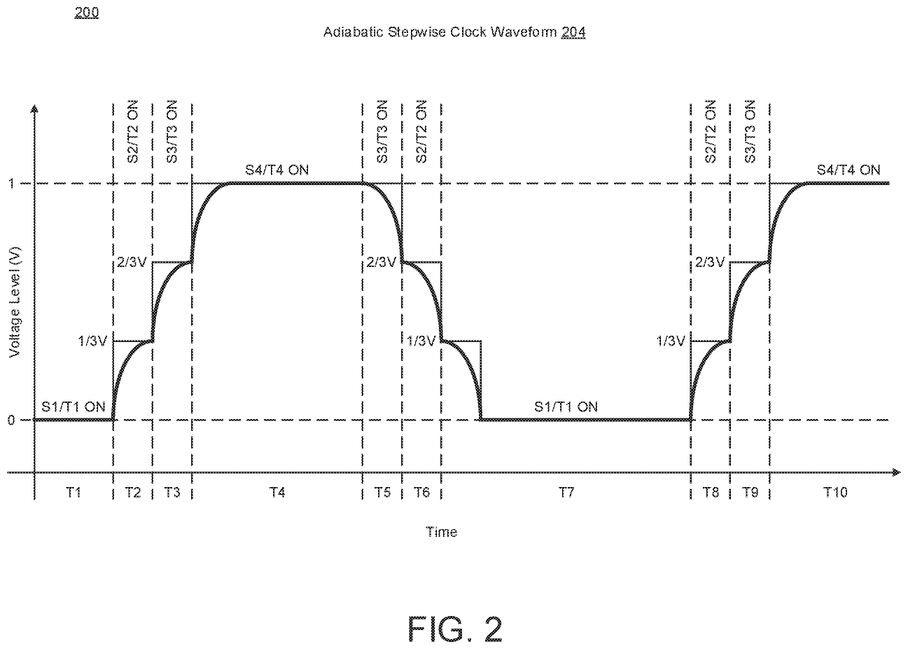

In various implementations, each selectively switched stage (Stage1, Stage2) may include a capacitor (C1, C2) and a transistor (T2, T3) coupled in series between the output node (n1) and ground (VSS or GND). Also, in some instances, each capacitor (C1, C2) may refer to an auxiliary tank capacitor that is separated (e.g., physically separated) and/or isolated (e.g., electrically isolated) from each other auxiliary tank capacitor. Also, the selectively switched stages (Stage1, Stage2) may include a first stage (Stage1) having a first capacitor (C1) and a second transistor (T2) coupled in series between the output node (n1) and ground (VSS or GND), and when selectively activated with a second switch signal (S2), the first stage (Stage1) provides a second voltage (V2) that is approximately one-third (⅓) of the supply voltage (VDD), such that V2=⅓*VDD. Also, the selectively switched stages (Stage1, Stage2) may include a second stage (Stage2) having a second capacitor (C2) and a third transistor coupled in series between the output node (n1) and ground (VSS or GND), and when selectively activated with a third switch signal (S3), the second stage (Stage2) provides a third voltage (V3) that is approximately two-thirds (⅔) of the supply voltage (VDD), such that V3=⅔*VDD. In addition, further scope, behavior and characteristics associated with the adiabatic stepwise clock signal (CLK_out) and the voltages (V1, V2, V3, V4) are further described in reference to FIG. 2.

In some implementations, each of the auxiliary tank capacitors have a positive electrode that may be separated (e.g., physically separated) and/or isolated (e.g., electrically isolated) from each other auxiliary tank capacitor, such that the supply voltage (VDD) that is coupled to each auxiliary tank capacitor is physically separated and/or electrically isolated from each other auxiliary tank capacitor. Also, in various applications, each of the auxiliary tank capacitors may share a common ground (VSS or GND) and/or common ground line.

In various implementations, the adiabatic clock driver circuitry 108 may include an output capacitor (Cclk) that is coupled between the output node (n1) and ground (VSS or GND), and the output capacitor (Cclk) may be charged by the adiabatic stepwise clock signal (CLK_out) by way of output node (n1). Also, the capacitance of the output capacitor (Cclk) may be approximately ( 3/20)*(C1+C2), such that capacitance of the first capacitor (C1) when added to the capacitance of the second capacitor (C2) may be approximately 20/3*Cclk, such that, e.g., C1+C2=(20/3)*Cclk=6.7*Cclk.

Also, in various applications, the output capacitor (Cclk) may comprise (as part thereof) various parasitic capacitances coupled with active device gate voltages. As such, the output capacitor (Cclk) may couple with different signals in reference to the power delivery network (PDN), such as, e.g., frontside PDN (FSPDN).

Therefore, under various conditions and functional activation modes, the output voltage of the adiabatic stepwise clock signal (CLK_out) may refer to V1 (e.g., V1=VSS or GND), V2 (e.g., V2=⅓*VDD), V3 (e.g., V3=⅔*VDD), or V4 (e.g., V4=VDD) at the output node (n1). Also, in some applications, the adiabatic clock driver circuitry 108 may provide selectively adjustable efficiency gain of the adiabatic stepwise clock signal based on a number of stages. Also, in some functional applications, the capacitance of the first capacitor (C1) when added to the capacitance of the second capacitor (C2) may equate to or may be approximately 20/3*Cclk, such that, e.g., C1+C2=6.7*Cclk.

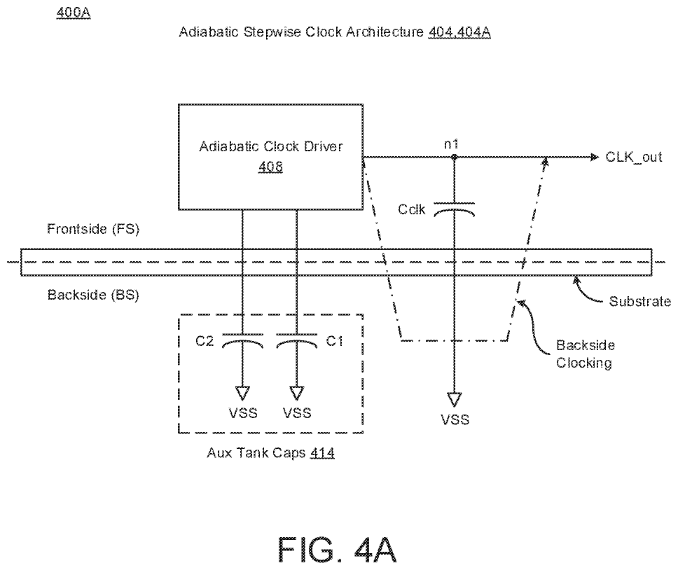

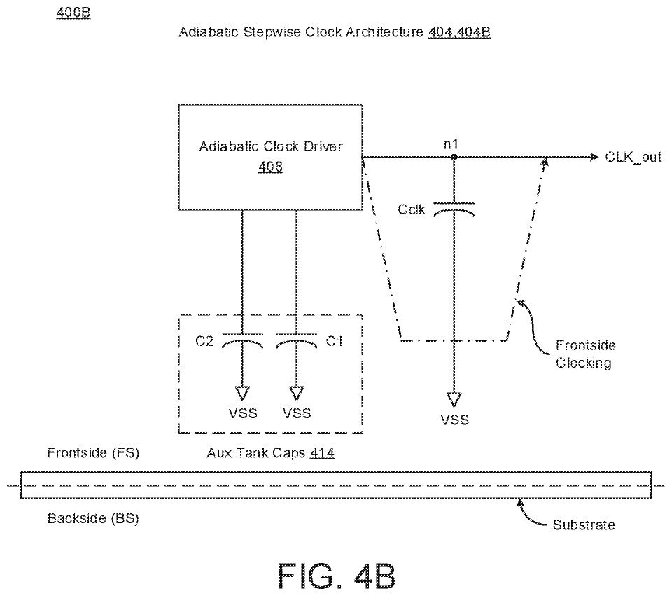

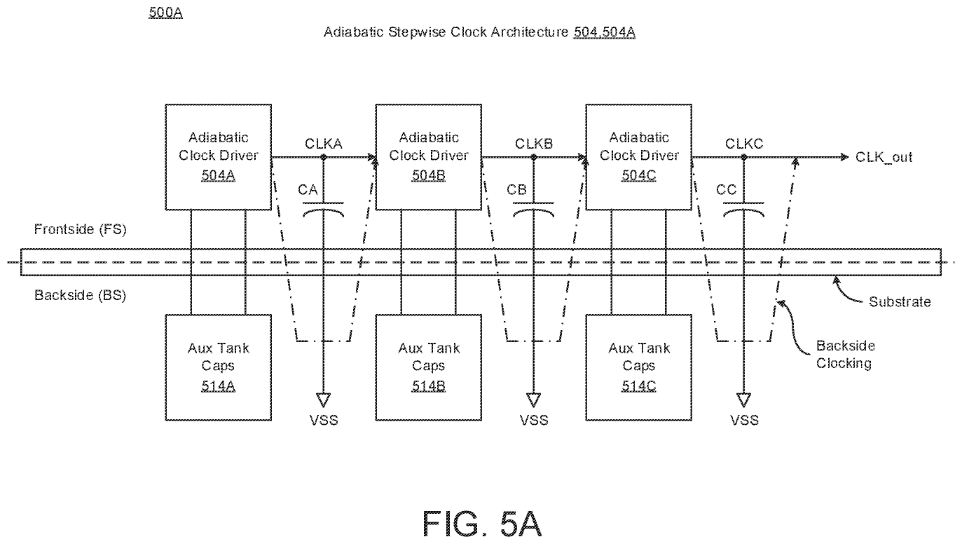

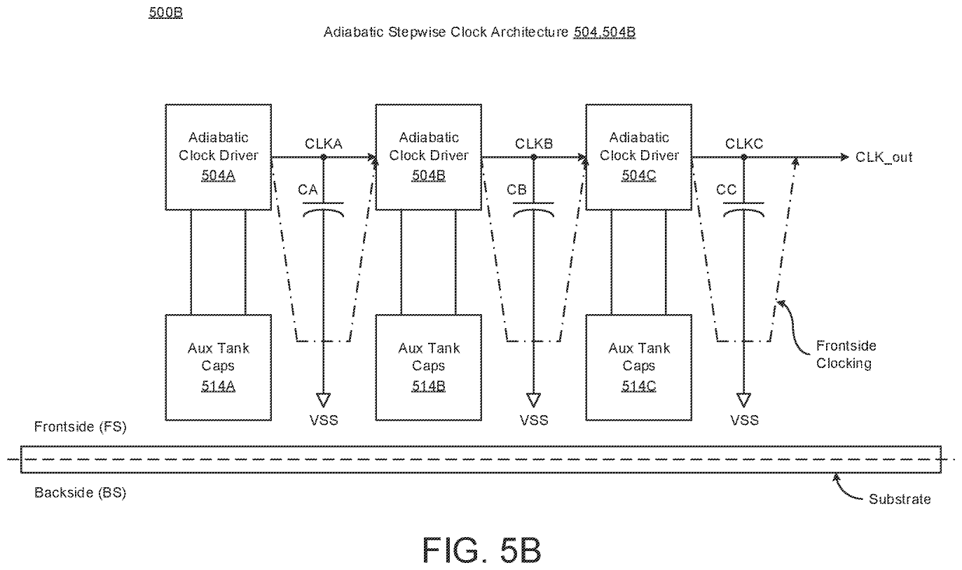

In some implementations, each capacitor (C1, C2) may refer to an auxiliary tank capacitor that is physically separated and/or electrically isolated from each other auxiliary tank capacitor, and also, each auxiliary tank capacitor (C1, C2) may refer to a MIMCAP (metal-insulator-metal capacitor). Also, in various implementations, as shown in FIGS. 4A and 5A, the adiabatic clock driver circuitry 108 may refer to frontside (FS) clock circuitry disposed above a substrate, and each auxiliary tank capacitor may be disposed below a substrate as part of a backside power distribution network (BSPDN) that is coupled to the frontside (FS) clock circuitry through the substrate. Further, in other implementations, as shown in FIGS. 4B and 5B, the adiabatic clock driver circuitry 108 may refer to frontside (FS) clock circuitry disposed above a substrate, and the auxiliary tank capacitors may also be disposed above a substrate as part of a frontside power distribution network (FSPDN) that is coupled to the frontside (FS) clock circuitry.

Moreover, in some implementations, the adiabatic clock driver circuitry 108 may include one or more additional adiabatic clock driver circuits 108, wherein each additional adiabatic clock driver circuits 108 is coupled in parallel with each other additional adiabatic clock driver circuits 108. Thus, the adiabatic clock driver circuitry 108 may include one or more additional clock drivers and one or more additional selectively switched stages of capacitors and transistors, wherein a combination of each additional clock driver and each additional selectively switched stage is coupled in parallel with a combination of each other additional clock driver and each other selectively switched stage. These forementioned concepts are shown, e.g., in FIGS. 5A-5B.

FIG. 2 illustrates a diagram 200 of an adiabatic stepwise clock waveform 204 in accordance with various implementations described herein. In various applications, the waveform diagram 200, 204 is associated with stepwise operation of the adiabatic clock architecture 104 in reference to FIG. 1.

As shown in FIG. 2, the diagram has an x-axis for time and a y-axis for voltage level of the adiabatic stepwise clock waveform 204. The x-axis for time has multiple timing periods (T1, T2, . . . , T10), and the y-axis for voltage level may refer to various logic levels between logic zero (0) and logic one (1), including, e.g., ⅓V and ⅔V, which may be stepped-up from 0V to ⅓V, ⅓V to ⅔V, ⅔V to 1V, and stepped-down vice-versa.

In timing period T1, the S1 signal may activate transistor T1 so that the voltage level of the adiabatic stepwise clock signal (CLK_out) is 0V.

In timing period T2, the S2 signal may activate transistor T2 so that the voltage level of the adiabatic stepwise clock signal (CLK_out) is stepped-up to ⅓V.

In timing period T3, the S3 signal may activate transistor T3 so that the voltage level of the adiabatic stepwise clock signal (CLK_out) is stepped-up again to ⅔V.

In timing period T4, the S4 signal may activate transistor T4 so that the voltage level of the adiabatic stepwise clock signal (CLK_out) is stepped-up again to 1V.

In timing period T5, the S3 signal may activate transistor T3 so that the voltage level of the adiabatic stepwise clock signal (CLK_out) is stepped-down to ⅔V.

In timing period T6, the S2 signal may activate transistor T2 so that the voltage level of the adiabatic stepwise clock signal (CLK_out) is stepped-down again to ⅓V.

In timing period T7, the S1 signal may activate transistor T1 so that the voltage level of the adiabatic stepwise clock signal (CLK_out) is stepped-down again to 0V.

This pattern in timing periods T1 to T7 may repeat, wherein in timing period T8, the S2 signal may activate transistor T2 so that the voltage level of the adiabatic stepwise clock signal (CLK_out) is stepped-up to ⅓V.

In timing period T9, the S3 signal may activate transistor T3 so that the voltage level of the adiabatic stepwise clock signal (CLK_out) is stepped-up again to ⅔V.

In timing period T10, the S4 signal may activate transistor T4 so that the voltage level of the adiabatic stepwise clock signal (CLK_out) is stepped-up again to 1V.

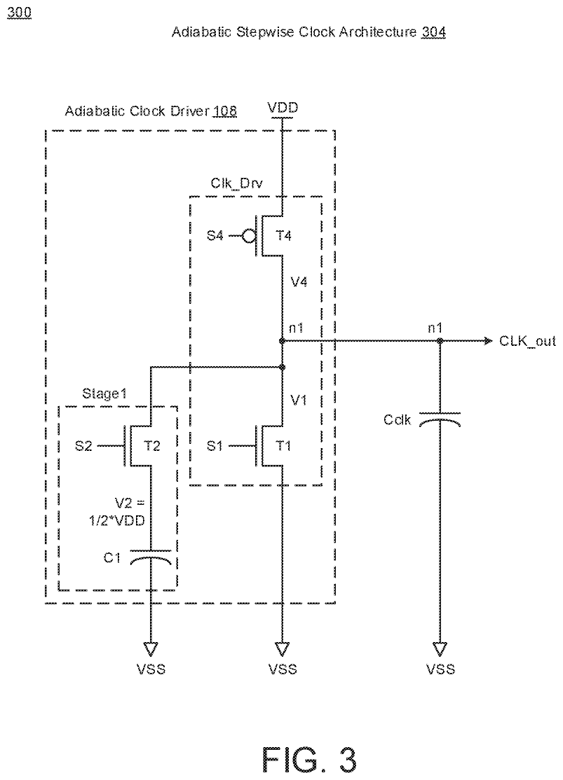

FIG. 3 illustrates a schematic diagram 300 of adiabatic clock architecture 304 in accordance with various implementations described herein. In various applications, the adiabatic clock architecture 304 as shown in FIG. 3 refers to a simplified implementation of the adiabatic clock architecture 104 as shown in FIG. 1.

In various implementations, the adiabatic clock architecture 304 in FIG. 3 may refer to adiabatic stepwise clocking architecture that may be implemented as a system or a device having various integrated circuit (IC) components that are arranged and coupled together as an assemblage or some combination of parts that provide for physical circuit designs and related structures. In some instances, a method of designing, providing and fabricating adiabatic clock architecture 304 as an integrated system or device may involve use of various IC circuit components and/or structures described herein so as to thereby implement fabrication schemes and techniques associated therewith. Also, the adiabatic clock architecture 304 may be integrated with various computing circuitry and/or related components on a single chip, and in addition, the adiabatic clock architecture 304 may be implemented in various embedded devices or systems for automotive, mobile, computer, server and Internet-of-things (loT) applications, including remote sensor nodes.

As shown in FIG. 3, the adiabatic clock architecture 304 may refer to adiabatic stepwise clocking architecture for various circuit related applications. Also, the adiabatic clock architecture 304 may include adiabatic clock driver circuitry 308 having a clock driver (Clk_Drv) and a single selectively switched stage (Stage1) that are configured to provide for adiabatic stepwise clock signal (CLK_out) as output. Also, the clock driver (Clk_Drv) provides the adiabatic stepwise clock signal (CLK_out) via the output node (n1), and the clock driver (Clk_Drv) may be coupled between a supply voltage (VDD) and ground (VSS or GND). Also, the selectively switched stage (Stage1) may include a capacitor (C1) and a transistor (T2) that are coupled in series between the output node (n1) and ground (VSS or GND), and also, the capacitor (C1) may be implemented as an auxiliary tank capacitor that is separated (e.g., physically separated) and/or isolated (e.g., electrically isolated) from each other auxiliary tank capacitor.

In various implementations, the clock driver (Clk_Drv) may include one or more transistors, including, e.g., a first transistor (T1) that is coupled between the output node (n1) and ground (VSS or GND), and when selectively activated with a first switch signal (S1), the clock driver (Clk_Drv) may provide a first voltage (V1) that is approximately equal to or at least similar to ground (VSS or GND) and/or ground voltage. Also, the clock driver (Clk_Drv) may include a second transistor (T4) that is coupled between the supply voltage (VDD) and the output node (n1), and when selectively activated with a fourth switch signal (S4), the clock driver (Clk_Drv) may provide a fourth voltage (V4) that is approximately equal to or at least similar to the supply voltage (VDD).

In various implementations, the selectively switched stage (Stage1) may have the capacitor (C1) and the transistor (T2) coupled in series between the output node (n1) and ground (VSS or GND). Also, in some instances, the capacitor (C1) may refer to an auxiliary tank capacitor. Also, when selectively activated with a second switch signal (S2), the first stage (Stage1) provides a different second voltage (V2) that is approximately one-half (½) of supply voltage (VDD), such that V2=½*VDD.

In various implementations, the adiabatic clock driver circuitry 308 may include an output capacitor (Cclk) that is coupled between the output node (n1) and ground (VSS or GND), and the output capacitor (Cclk) may be charged by the adiabatic stepwise clock signal (CLK_out) by way of output node (n1). Also, in some functional applications, the capacitance of the first capacitor (C1=6.7Cclk) when added to the capacitance of the second capacitor (C2=0) may equate to or may be approximately 20/3*Cclk, such that, e.g., C1+C2=. 6.7*Cclk.

Therefore, under various conditions and functional activation modes, the output voltage of the adiabatic stepwise clock signal (CLK_out) may refer to V1 (e.g., V1=VSS or GND), V2 (e.g., V2=½*VDD), or V4 (e.g., V4=VDD) at the output node (n1). Also, in various implementations, the adiabatic clock driver circuitry 308 may provide selectively adjustable efficiency gain of the adiabatic stepwise clock signal based on the number of stages. Also, in various functional applications, the capacitance of the first capacitor (C1) may equate to or may be approximately ½*Cclk, such that, e.g., C1=0.5*Cclk.

In various implementations, the capacitor (C1) is an auxiliary tank capacitor that is physically separated and/or electrically isolated from each other auxiliary tank capacitor, and also, the auxiliary tank capacitor (C1) may refer to a MIMCAP (metal-insulator-metal capacitor). Also, in various implementations, the adiabatic clock driver circuitry 308 may refer to FS clock circuitry disposed above substrate, and the auxiliary tank capacitor may be disposed below substrate as part of a BSPDN that is coupled to the FS clock circuitry through the substrate. Further, in some other implementations, the adiabatic clock driver circuitry 308 may refer to FS clock circuitry disposed above substrate, and auxiliary tank capacitor may also be disposed above substrate as part of an FSPDN that is coupled to the FS clock circuitry.

In some implementations, the adiabatic clock driver circuitry 308 may have one or more one or more additional adiabatic clock driver circuits 308, wherein each additional adiabatic clock driver circuits 308 is coupled in parallel with each other additional adiabatic clock driver circuits 308. Thus, the adiabatic clock driver circuitry 308 may include one or more additional clock drivers and one or more additional selectively switched stages of a capacitor and a transistor, wherein a combination of each additional clock driver and each additional selectively switched stage is coupled in parallel with a combination of each other additional clock driver and each other selectively switched stage.

FIG. 4A-4B illustrate clocking operational diagrams 400A, 400B for adiabatic clock architecture 404 in accordance with implementations described herein. In particular, FIG. 4A shows a clocking operational diagram 400A of backside clocking operation of adiabatic clock architecture 404A, and FIG. 4B shows a clocking operational diagram 400B of frontside clocking operation of adiabatic clock architecture 404B. In this instance, adiabatic clock architectures 404, 404A, 404B as shown in FIGS. 4A-4B are associated with the adiabatic clock architecture 104 as shown in FIG. 1.

In various implementations, the adiabatic clock architecture 404, 404A, 404B in FIGS. 4A-4B refer to adiabatic stepwise clocking architecture that may be implemented as a system or device having various integrated circuit (IC) components that are arranged and coupled together as an assemblage or some combination of parts that provide for physical circuit designs and related structures. In some instances, a method of designing, providing and fabricating adiabatic clock architecture as an integrated system or device may involve use of various IC circuit components and/or structures described herein so as to thereby implement fabrication schemes and techniques associated therewith. Also, the adiabatic clock architecture may be integrated with various computing circuitry and/or related components on a single chip, and in addition, the adiabatic clock architecture may be implemented in some embedded devices or systems for automotive, mobile, computer, server and Internet-of-things (loT) applications, including remote sensor nodes.

As shown in FIG. 4A, the adiabatic clock architecture 404A refers to adiabatic stepwise clocking architecture for various circuit related applications. Also, the adiabatic clock architecture 404A has adiabatic clock driver circuitry 408 formed frontside (FS) and auxiliary tank capacitors 414 formed backside (BS). Also, adiabatic clock driver circuitry 408 may have clock driver (Clk_Drv with T1/T4) and selectively switched stages (Stage1, Stage2) of transistors (T2, T3) formed frontside (FS) with the auxiliary tank capacitors 414 (C1, C2) formed backside (BS). Also, adiabatic clock driver circuitry 408 refers to frontside (FS) clock circuitry that is disposed above substrate, and the auxiliary tank capacitors 414 (C1, C2) are MIMCAPs that are disposed below the substrate as part of a backside power distribution network (BSPDN) that is coupled to FS clock circuitry through substrate. Also, with backside (BS) placement of the auxiliary tank capacitors 414 (C1, C2), the adiabatic clock architecture 404A provides for backside clocking of the adiabatic stepwise clocking signal (CLK_out), as shown, e.g., in FIG. 4A.

In some implementations, adiabatic clock driver circuitry 408 and auxiliary tank capacitors 414 (C1, C2) are configured to provide for the adiabatic stepwise clock signal (CLK_out) as output. Also, each selectively switched stage (Stage1, Stage2) may include a capacitor (C1, C2) and a transistor (T2, T3) coupled in series between the output node (n1) and ground (VSS or GND). Also, capacitors (C1, C2) refer to auxiliary tank capacitors that are separated (e.g., physically separated) and isolated (e.g., electrically isolated) from each other auxiliary tank capacitor. In various applications, the auxiliary tank capacitors may be separated (e.g., physically separated) and isolated (e.g., electrically isolated) from each other auxiliary tank capacitor, such that the supply voltage (VDD) that is coupled to each auxiliary tank capacitor is physically separated and electrically isolated from each other auxiliary tank capacitor. Also, in various applications, the auxiliary tank capacitors may share a common ground (VSS or GND) and/or ground line.

In various other implementations, as shown in FIG. 4B, adiabatic clock driver circuitry 408 may have the clock driver (Clk_Drv: T1/T4) and selectively switched stages (Stage1, Stage2) of transistors (T2, T3) in the adiabatic clock driver 408 formed frontside (FS), and the auxiliary tank capacitors 414 may have capacitors (C1, C2) that are also formed frontside (FS). Also, in this instance, the adiabatic clock driver circuitry 408 refers to frontside (FS) clock circuitry that is disposed above a substrate, and the auxiliary tank capacitors 414 may also be disposed above substrate as part of the frontside (FS) power distribution network (FSPDN) that is coupled to the frontside (FS) clock circuitry.

FIG. 5A-5B illustrate clocking operational diagrams 500A, 500B for adiabatic clock architecture 504 in accordance with implementations described herein. In particular, FIG. 5A shows a clocking operational diagram 500A of backside clocking operation of adiabatic clock architecture 504A, and FIG. 5B shows a clocking operational diagram 500B of frontside clocking operation of adiabatic clock architecture 504B. In this instance, adiabatic clock architectures 504, 504A, 504B as shown in FIGS. 5A-5B are associated with the adiabatic clock architecture 104, 404 as shown in FIGS. 1 and 4A-4B.

In various implementations, the adiabatic clock architecture 504, 504A, 504B in FIGS. 5A-5B refer to adiabatic stepwise clocking architecture that may be implemented as a system or device having various integrated circuit (IC) components that are arranged and coupled together as an assemblage or some combination of parts that provide for physical circuit designs and related structures. In some instances, a method of designing, providing and fabricating adiabatic clock architecture as an integrated system or device may involve use of various IC circuit components and/or structures described herein so as to thereby implement fabrication schemes and techniques associated therewith. Also, the adiabatic clock architecture may be integrated with various computing circuitry and/or related components on a single chip, and in addition, the adiabatic clock architecture may be implemented in some embedded devices or systems for automotive, mobile, computer, server and Internet-of-things (loT) applications, including remote sensor nodes.

As shown in FIG. 5A, the adiabatic clock architecture 504 refers to adiabatic stepwise clocking architecture for various circuit related applications. Also, the adiabatic clock architecture 504 has multiple adiabatic clock driver circuits (504A/514A, 504B/514B, 504C/514C) coupled in series so as to selectively adjust efficiency gain of the adiabatic stepwise clock signal (CLK_out). Also, in various applications, each adiabatic clock driver circuit (504A/514A, 504B/514B, 504C/514C) includes a clock driver (Clk_Drv: T1/T4) and selectively switched stages of transistors (504A, 504B, 504C) and MIM-capacitors (514A, 514B, 514C) that provide for the adiabatic stepwise clock signal (CLK_out). Also, in some applications, as described herein, each selectively switched stage has a MIM-capacitor (C1, C2) and a transistor (T2, T3) that are coupled in series between the output node (n1) and ground (VSS or GND) of each selectively switched stage, in a manner as described herein in reference to FIG. 1.

In various applications, each capacitor refers to an auxiliary tank capacitor that is physically separated and/or electrically isolated from each other auxiliary tank capacitor, and in addition, each auxiliary tank capacitor refers to a MIMCAP (metal-insulator-metal capacitor). Also, each clock driver (Clk_Drv: T1/T4) includes a first transistor (T1) coupled between the output node (n1) and ground (VSS or GND) of each corresponding adiabatic clock driver circuit, and when selectively activated with a first switch signal (S1), the clock driver provides the first voltage (V1) that is approximately similar to ground (VSS or GND) or a ground voltage. Also, the selectively switched stages (Stage1, Stage2) include a first stage (Stage1) having a first capacitor (C1) and a second transistor (T2) coupled in series between the output node (n1) and ground (VSS or GND), and when selectively activated with a second switch signal (S2), the first stage (Stage1) provides a second voltage (V2) approximately one-third (⅓) of a supply voltage (VDD), such that V2=⅓*VDD. Also, the selectively switched stages (Stage1, Stage2) include a second stage (Stage2) having a second capacitor (C2) and a third transistor (T3) coupled in series between the output node (n1) and ground (VSS or GND), and when selectively activated with a third switch signal (S3), the second stage (Stage2) provides a third voltage (V3) that is approximately two-thirds (⅔) of supply voltage (VDD), such that V3=⅔*VDD. Also, each clock driver (Clk_Drv: T1/T4) has a fourth transistor (T4) coupled between the supply voltage (VDD) and the output node (n1) of each corresponding adiabatic clock driver circuit, and when selectively activated with a fourth switch signal (S4), the clock driver provides a fourth voltage (V4) that is approximately similar to the supply voltage (VDD).

In various implementations, each adiabatic clock driver circuit (504A, 504B, 504C) includes an output capacitor (Cclk) that is coupled between output node (n1) and ground (VSS or GND) for each corresponding adiabatic clock driver circuit (504A, 504B, 504C). Also, each output capacitor (Cclk) may be charged by the adiabatic stepwise clock signal (CLK_out) for each corresponding adiabatic clock driver circuit.

In various implementations, as shown in FIG. 5A, the multiple adiabatic clock driver circuits (504A, 504B, 504C) refer to frontside (FS) clock circuitry disposed above a substrate, and also, each auxiliary tank capacitor (514A, 514B, 514C) is disposed below the substrate as part of a backside power distribution network (BSPDN) that is coupled to the frontside (FS) clock circuitry through a substrate. Also, with backside (BS) placement of the auxiliary tank capacitors (514A, 514B, 514C), the adiabatic clock architecture 504 provides for backside clocking of the adiabatic stepwise clocking signal (CLK_out).

Also, in some implementations, each adiabatic clock driver circuit (504A, 504B, 504C) may have one or more additional clock drivers and one or more selectively switched stages of capacitors and transistors, and also a combination of each additional clock driver and each additional selectively switched stage may be coupled in parallel with each other combination of clock drivers and additional selectively switched stages.

In various other implementations, as shown in FIG. 5B, the multiple adiabatic clock driver circuits (504A, 504B, 504C) may be disposed frontside as frontside (FS) clock circuitry disposed above a substrate, and also, each auxiliary tank capacitor (514A, 514B, 514C) may be disposed above substrate as part of a frontside power distribution network (FSPDN) that is coupled to the frontside (FS) clock circuitry above the substrate.

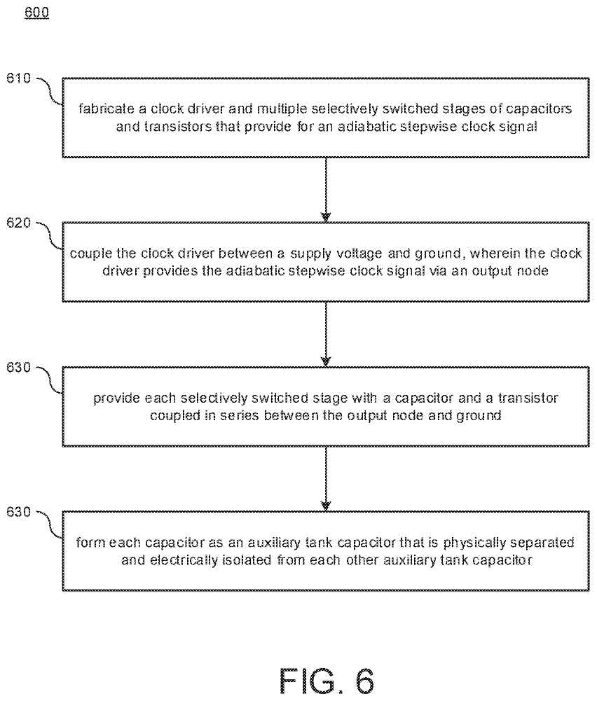

FIG. 6 illustrates a process diagram of a method 600 for providing adiabatic clock architecture in accordance with various implementations described herein.

It should be understood that even though the method 600 indicates a particular order of operation execution, in some instances, various certain portions of the operations may be executed in a different order, and on different systems. In other cases, additional operations and/or steps may be added to and/or omitted from method 600. Also, method 600 may be implemented in hardware and/or software. If implemented in hardware, the method 600 may be implemented with various components and/or circuitry, as described herein in reference to FIGS. 1-3, 4A-4B and 5A-5B. Also, if implemented in software, the method 600 may be implemented with program and/or software instruction processes configured for providing register bank architecture with latches, as described herein. Moreover, if implemented in software, instructions related to implementing the method 600 may be stored in memory and/or a database. In various instances, a computer or various other types of computing devices having a processor and memory may be configured to perform method 600.

In various implementations, method 600 may refer to a method for designing, providing, fabricating and/or manufacturing adiabatic clock architecture as an integrated system, device and/or circuit that involves use of various IC circuit components described herein so as to thereby implement adiabatic stepwise clocking schemes and techniques associated therewith. The adiabatic clock architecture may be integrated with computing circuitry and related components on a single chip, and the adiabatic clock architecture may be implemented in embedded systems for various electronic, mobile and Internet-of-things (loT) applications, including sensor nodes, including remote sensor nodes.

At block 610, the method 600 may be configured to fabricate a clock driver and multiple selectively switched stages of capacitors and transistors that provide for adiabatic stepwise clock signal as output. At block 620, method 600 may be configured to couple the clock driver between a supply voltage (VDD) and ground (VSS or GND), wherein the clock driver provides the adiabatic stepwise clock signal via an output node (n1). Also, at block 630, method 600 may be configured to provide each selectively switched stage with a capacitor and a transistor coupled in series between the output node (n1) and ground (VSS or GND). Also, at block 640, method 600 may be configured to form each capacitor as an auxiliary tank capacitor (e.g., MIMCAP) that is physically separated and electrically isolated from each other auxiliary tank capacitor.

It should be intended that the subject matter of the claims not be limited to the implementations and illustrations provided herein, but include modified forms of those implementations including portions of implementations and combinations of elements of different implementations in accordance with the claims. It should be appreciated that in the development of any such implementation, as in any engineering or design project, numerous implementation-specific decisions should be made to achieve developers' specific goals, such as compliance with system-related and business related constraints, which may vary from one implementation to another. Moreover, it should be appreciated that such a development effort may be complex and time consuming, but would nevertheless be a routine undertaking of design, fabrication, and manufacture for those of ordinary skill having benefit of this disclosure.

Described herein are various implementations of a device with a clock driver that provides an adiabatic stepwise clock signal via an output node, and the clock driver may be coupled between a supply voltage and ground. The device may have selectively switched stages with each selectively switched stage having a capacitor and a transistor coupled in series between the output node and ground. In some implementations, each capacitor may refer to an auxiliary tank capacitor that is electrically isolated from each other auxiliary tank capacitor.

Described herein are various implementations of a device having multiple adiabatic clock driver circuits coupled in series so as to selectively adjust efficiency gain of an adiabatic stepwise clock signal. In some implementations, each adiabatic clock driver circuit may include a clock driver coupled between a supply voltage and ground, and each clock driver may provide the adiabatic stepwise clock signal via an output node of each corresponding adiabatic clock driver circuit. Also, in some implementations, each adiabatic clock driver circuit may have multiple selectively switched stages of capacitors and transistors, and also, each selectively switched stage may have a capacitor and a transistor coupled in series between the output node and ground of each corresponding adiabatic clock driver circuit.

Described herein are various implementations of a method. The method may fabricate a clock driver and multiple selectively switched stages of capacitors and transistors that provide for an adiabatic stepwise clock signal. The method may couple the clock driver between a supply voltage and ground, and the clock driver may provide the adiabatic stepwise clock signal via an output node. The method may provide each selectively switched stage with a capacitor and a transistor coupled in series between the output node and ground. The method may form each capacitor as an auxiliary tank capacitor that is electrically isolated from each other auxiliary tank capacitor.

Reference has been made in detail to various implementations, examples of which are illustrated in the accompanying drawings and figures. In the following detailed description, numerous specific details are set forth to provide a thorough understanding of the disclosure provided herein. However, the disclosure provided herein may be practiced without these specific details. In some other instances, well-known methods, procedures, components, circuits and networks have not been described in detail so as not to unnecessarily obscure details of the embodiments.

It should also be understood that, although the terms first, second, etc. may be used herein to describe various elements, these elements should not be limited by these terms. These terms are only used to distinguish one element from another. For example, a first element could be termed a second element, and, similarly, a second element could be termed a first element. The first element and the second element are both elements, respectively, but they are not to be considered the same element.

The terminology used in the description of the disclosure provided herein is for the purpose of describing particular implementations and is not intended to limit the disclosure provided herein. As used in the description of the disclosure provided herein and appended claims, the singular forms “a,” “an,” and “the” are intended to include the plural forms as well, unless the context clearly indicates otherwise. The term “and/or” as used herein refers to and encompasses any and all possible combinations of one or more of the associated listed items. The terms “includes,” “including,” “comprises,” and/or “comprising,” when used in this specification, specify a presence of stated features, integers, steps, operations, elements, and/or components, but do not preclude the presence or addition of one or more other features, integers, steps, operations, elements, components and/or groups thereof.

As used herein, the term “if” may be construed to mean “when” or “upon” or “in response to determining” or “in response to detecting,” depending on the context. Similarly, the phrase “if it is determined” or “if [a stated condition or event] is detected” may be construed to mean “upon determining” or “in response to determining” or “upon detecting [the stated condition or event]” or “in response to detecting [the stated condition or event],” depending on the context. The terms “up” and “down”; “upper” and “lower”; “upwardly” and “downwardly”; “below” and “above”; and other similar terms indicating relative positions above or below a given point or element may be used in connection with some implementations of various technologies described herein.

While the foregoing is directed to implementations of various related techniques described herein, other and further implementations may be devised in accordance with the disclosure herein, which may be determined by the claims that follow.

Although the subject matter has been described herein in language specific to structural features and/or methodological acts, it should be understood that the subject matter defined in the appended claims is not necessarily limited to the specific features or acts described above. Rather, specific features and acts described above are disclosed as example forms of implementing the claims.

What is claimed is:

1. A device comprising:
a clock driver that provides an adiabatic stepwise clock signal via an output node, wherein the clock driver is coupled between a supply voltage and ground; and
selectively switched stages with each selectively switched stage having a capacitor and a transistor coupled in series between the output node and ground, wherein each capacitor refers to an auxiliary tank capacitor that is electrically isolated from each other auxiliary tank capacitor.

2. The device of claim 1, wherein:
the clock driver has a first transistor coupled between the output node and ground, and
when selectively activated with a first switch signal, the clock driver provides a first voltage that is approximately similar to ground or a ground voltage.

3. The device of claim 1, wherein:
the selectively switched stages include a first stage having a first capacitor and a second transistor coupled in series between the output node and ground, and
when selectively activated with a second switch signal, the first stage provides a second voltage that is approximately one-third (⅓) of the supply voltage.

4. The device of claim 1, wherein:
the selectively switched stages include a second stage having a second capacitor and a third transistor coupled in series between the output node and ground, and
when selectively activated with a third switch signal, the second stage provides a third voltage that is approximately two-thirds (⅔) of a supply voltage.

5. The device of claim 1, wherein:
the clock driver has a fourth transistor coupled between the supply voltage and the output node, and
when selectively activated with a fourth switch signal, the clock driver provides a fourth voltage that is approximately similar to the supply voltage.

6. The device of claim 1, further comprising:
an output capacitor coupled between the output node and ground,
wherein the output capacitor is charged by the adiabatic stepwise clock signal.

7. The device of claim 1, wherein each auxiliary tank capacitor refers to a MIMCAP (metal-insulator-metal capacitor).

8. The device of claim 1, wherein:
the adiabatic clock driver circuitry refers to frontside clock circuitry that is disposed above a substrate, and
each auxiliary tank capacitor is disposed above the substrate as part of a frontside power distribution network that is coupled to the frontside clock circuitry.

9. The device of claim 1, wherein:
the adiabatic clock driver circuitry refers to frontside clock circuitry that is disposed above a substrate,
each auxiliary tank capacitor is disposed below the substrate as part of a backside power distribution network that is coupled to the frontside clock circuitry through the substrate.

10. The device of claim 1, further comprising:
one or more additional clock drivers; and
one or more additional selectively switched stages of capacitors and transistors,
wherein combination of each additional clock driver and each additional selectively switched stage is coupled in parallel with combination of each other additional clock driver and each other selectively switched stage.

11. A device comprising:
multiple adiabatic clock driver circuits coupled in series so as to selectively adjust efficiency gain of an adiabatic stepwise clock signal,
wherein each adiabatic clock driver circuit includes a clock driver coupled between a supply voltage and ground, and each clock driver provides the adiabatic stepwise clock signal via an output node of each corresponding adiabatic clock driver circuit, and
wherein each adiabatic clock driver circuit has multiple selectively switched stages of capacitors and transistors, and each selectively switched stage has a capacitor and a transistor coupled in series between the output node and ground of each corresponding adiabatic clock driver circuit.

12. The device of claim 11, wherein:
each capacitor refers to an auxiliary tank capacitor that is electrically isolated from each other auxiliary tank capacitor, and
each auxiliary tank capacitor refers to a MIMCAP (metal-insulator-metal capacitor).

13. The device of claim 11, wherein:
each clock driver includes a first transistor coupled between the output node and ground of each corresponding adiabatic clock driver circuit, and
when selectively activated with a first switch signal, the clock driver provides a first voltage that is approximately similar to ground or a ground voltage.

14. The device of claim 11, wherein:
the selectively switched stages include a first stage having a first capacitor and a second transistor coupled in series between the output node and ground, and
when selectively activated with a second switch signal, the first stage provides a second voltage that is approximately one-third (⅓) of a supply voltage.

15. The device of claim 11, wherein:
the selectively switched stages include a second stage having a second capacitor and a third transistor coupled in series between the output node and ground, and
when selectively activated with a third switch signal, the second stage provides a third voltage that is approximately two-thirds (⅔) of a supply voltage.

16. The device of claim 11, wherein:
each clock driver has a fourth transistor coupled between the supply voltage and the output node of each corresponding adiabatic clock driver circuit, and
when selectively activated with a fourth switch signal, the clock driver provides a fourth voltage that is approximately similar to the supply voltage.

17. The device of claim 1, wherein:
each adiabatic clock driver circuit has an output capacitor,
each output capacitor is coupled between the output node and ground for each corresponding adiabatic clock driver circuit, and
the output capacitor is charged by the adiabatic stepwise clock signal for each corresponding adiabatic clock driver circuit.

18. The device of claim 11, wherein:
the multiple adiabatic clock driver circuits refer to frontside clock circuitry that is disposed above a substrate, and
each auxiliary tank capacitor is disposed above the substrate as part of a frontside power distribution network that is coupled to the frontside clock circuitry.

19. The device of claim 11, wherein:
the multiple adiabatic clock driver circuits refer to frontside clock circuitry that is disposed above a substrate, and
each auxiliary tank capacitor is disposed below the substrate as part of a backside power distribution network that is coupled to the frontside clock circuitry through the substrate.

20. A method comprising:
fabricating a clock driver and multiple selectively switched stages of capacitors and transistors that provide for an adiabatic stepwise clock signal;
coupling the clock driver between a supply voltage and ground, wherein the clock driver provides the adiabatic stepwise clock signal via an output node;
providing each selectively switched stage with a capacitor and a transistor coupled in series between the output node and ground; and
forming each capacitor as an auxiliary tank capacitor that is electrically isolated from each other auxiliary tank capacitor.
